(19) United States
(12) Patent Application Publication
(10) Pub. No.: US 2017/0011886 A1
(43) Pub. Date: Jan. 12, 2017

(54) PLASMA PROCESSING APPARATUS

(71) Applicants: TOKYO ELECTRON LIMITED, Tokyo (JP); TOHOKU TECHNO ARCH CO., LTD, Miyagi (JP)

(72) Inventors: Toshihisa NOZAWA, Miyagi (JP); Kazuki MOYAMA, Miyagi (JP); Ryo MIYAMA, Miyagi (JP); Seiji SAMUKAWA, Miyagi (JP)

(73) Assignees: TOKYO ELECTRON LIMITED, Tokyo (JP); TOHOKU TECHNO ARCH CO., LTD, Miyagi (JP)

(21) Appl. No.: 15/203,982

(22) Filed: Jul. 7, 2016

(30) Foreign Application Priority Data
Jul. 10, 2015 (JP) 2015-139019

(51) Int. Cl. H01J 37/32; C23C 16/50

(52) U.S. Cl. CPC H01J 37/32009; C23C 16/50; H01J 2237/334; H01J 2237/332

(57) ABSTRACT

Disclosed is a plasma processing apparatus including: a processing container; and a partition plate made of an insulating material, having a plurality of openings, and configured to partition an inside of the processing container into a plasma generating chamber and a processing chamber. A first conductive member made of a conductive material is provided on a surface of the processing chamber side of the partition plate, and the first conductive member is applied with at least one of an AC voltage, and a DC voltage of a polarity that is opposite to a polarity of charged particles guided from the plasma generating chamber into the processing chamber through each of the openings.

### CROSS-REFERENCE TO RELATED APPLICATIONS

This application is based on and claims priority from Japanese Patent Application No. 2015-139019 filed on Jul. 10, 2015 with the Japan Patent Office, the disclosure of which is incorporated herein in its entirety by reference.

### TECHNICAL FIELD

Various aspects and exemplary embodiments of the present disclosure relate to a plasma processing apparatus.

### BACKGROUND

In a conventional processing apparatus, a partition plate having a plurality of openings is provided in a processing container, so that the processing container is partitioned into a beam generating chamber and a processing chamber by the partition plate. When ions in plasma generated in the beam generating chamber pass through the plurality of openings, the partition plate donates electrons to the ions so that the ions are neutralized. When a processing gas is irradiated with particles obtained by the neutralization of the ions (hereinafter, referred to as “neutral particles”) in the processing chamber, the processing gas is excited, and active species produced from the processing gas fall onto a workpiece placed on a placing table in the processing chamber. Accordingly, a desired processing such as, for example, film formation or etching, is performed on the workpiece. As a processing apparatus for performing a processing using the neutral particles, a neutral particle beam processing apparatus has been known (see, e.g., Japanese Patent Laid-Open Publication No. 2002-289399).

In the neutral particle beam processing apparatus, among ions and electrons produced in the beam processing chamber, the electrons reach the partition plate first because of their faster moving speed. Then, the surface of the partition plate, which is made of a dielectric, is negatively charged, and a sheath occurs near the surface of the beam generating chamber side of the partition plate. Thus, the ions in the plasma are accelerated in a direction toward the partition plate, and some of the ions pass through the openings formed in the partition plate. When the ions pass through the openings of the partition plate, the ions are electrically neutralized by charge exchange with the electrons charged on the sidewall of the openings, and become neutral particles, which are then released into the processing chamber.

### SUMMARY

In an aspect of the present disclosure, a plasma processing apparatus includes a processing container and a partition plate. The partition plate is made of an insulating material, has a plurality of openings, and partitions an inside of the processing container into a plasma generating chamber and a processing chamber. Further, a first conductive member made of a conductive material is provided on a surface of the processing chamber side of the partition plate. The first conductive member is applied with at least one of an AC voltage and a DC voltage of a polarity that is opposite to a polarity of charged particles guided from the plasma generating chamber into the processing chamber through each of the openings.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an exemplary plasma processing apparatus.

FIG. 2 is a plan view illustrating an exemplary slot plate.

FIG. 3 is an enlarged cross-sectional view illustrating an exemplary configuration of a partition plate.

FIG. 4 is an enlarged cross-sectional view illustrating an exemplary partition plate in Modification 1.

FIG. 5 is an enlarged cross-sectional view illustrating an exemplary partition plate in Modification 2.

FIG. 6 is a plan view illustrating the exemplary partition plate in Modification 2.

FIG. 7 is an enlarged cross-sectional view illustrating an exemplary partition plate in Modification 3.

FIG. 8 is an enlarged cross-sectional view illustrating an exemplary partition plate in Modification 4.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the neutral particle beam processing apparatus described in Japanese Patent Laid-Open Publication No. 2002-289399, the ions in the plasma may be drawn by the sheath occurring near the surface of the beam generating chamber side of the partition plate, thereby colliding with the partition plate. When the ions collide with the partition plate, the surface of the partition plate is scraped, and thus, consumption of the partition plate may be accelerated.

In addition, when the ions collide with the partition plate, the surface of the partition plate is scraped, and thus, the material of the partition plate may be scattered as particles in the beam generating chamber. When the particles are scattered in the beam generating chamber, the scattered particles may pass through the openings of the partition plate, enter into the processing chamber, and adhere to the workpiece in the processing chamber. Thus, the workpiece may be contaminated by the particles.

In an aspect of the present disclosure, a plasma processing apparatus includes a processing container and a partition plate. The partition plate is made of an insulating material, has a plurality of openings, and partitions an inside of the processing container into a plasma generating chamber and a processing chamber. Further, a first conductive member made of a conductive material is provided on a surface of the processing chamber side of the partition plate. The first conductive member is applied with at least one of an AC voltage and a DC voltage of a polarity that is opposite to a polarity of charged particles guided from the plasma generating chamber into the processing chamber through each of the openings.

In an exemplary embodiment of the disclosed plasma processing apparatus, the first conductive member may be formed by coating the conductive material on the surface of the processing chamber side of the partition plate.

In an exemplary embodiment of the disclosed plasma processing apparatus, at least a part of an inner wall of each of the plurality of openings may be coated with the conductive material. The first conductive member may be conductive with the conductive material coated on the inner wall of each of the plurality of openings.

In an exemplary embodiment of the disclosed plasma processing apparatus, the first conductive member may be formed as a member separate from the partition plate, and attached to the surface of the processing chamber side of the partition plate.

In an exemplary embodiment of the disclosed plasma processing apparatus, a second conductive member made of a conductive material may be provided on the plasma generating chamber side of the partition plate, and the second conductive member may be connected to a reference potential of the processing container.

In an exemplary embodiment of the disclosed plasma processing apparatus, a second conductive member made of a conductive material may be provided on the plasma generating chamber side of the partition plate, and the second conductive member may be applied with a DC voltage of a polarity that is equal to a polarity of charged particles included in plasma generated in the plasma generating chamber, and guided into the processing chamber through each of the openings.

In an exemplary embodiment of the disclosed plasma processing apparatus, a magnitude of the DC voltage applied to the second conductive member may be substantially equal to a magnitude of a plasma potential of the plasma generated in the plasma generating chamber.

In an exemplary embodiment of the disclosed plasma processing apparatus, each of the plurality of openings may have an opening area at the plasma generating chamber side wider than an opening area at the plasma generating chamber side.

According to various aspects and exemplary embodiments, the consumption of the partition plate and the contamination of the workpiece may be suppressed.

Hereinafter, exemplary embodiments of the plasma processing apparatus disclosed herein will be described in detail with reference to the drawings. Further, the present disclosure is not limited to the exemplary embodiments disclosed herein. In addition, respective embodiments may be appropriately combined within a range that does not contradict the processing contents.

### Exemplary Embodiment

### Plasma Processing Apparatus 10

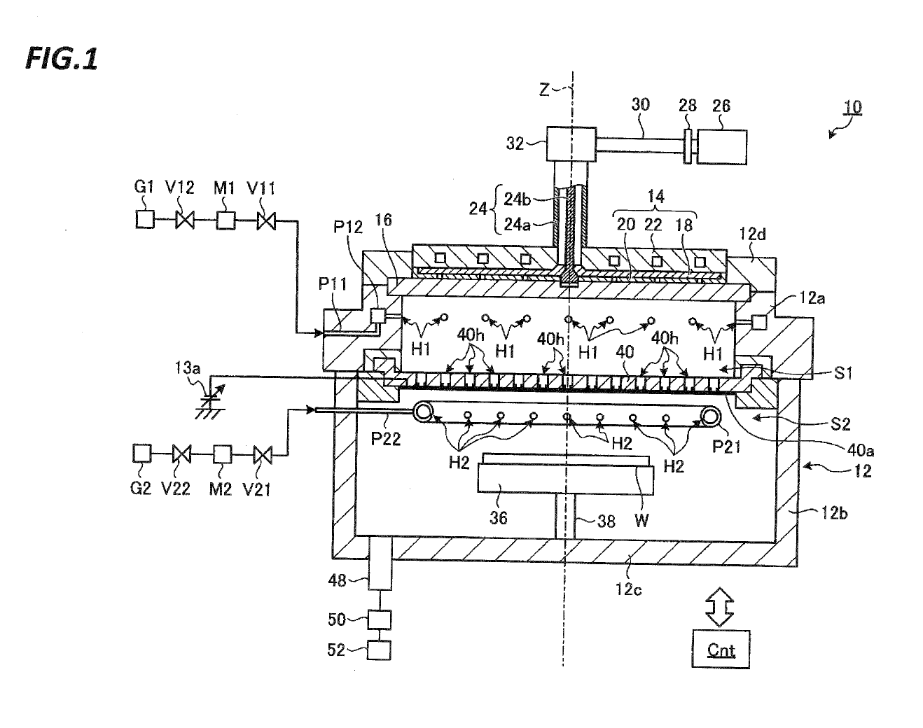

FIG. 1 is a cross-sectional view illustrating an exemplary plasma processing apparatus 10. The plasma processing apparatus 10 illustrated in FIG. 1 includes a processing container 12. The processing container 12 is a substantially cylindrical container that extends in a direction where an axis Z illustrated in FIG. 1 extends (hereinafter, referred to as an “axis Z direction”), and defines a space therein. The space is partitioned into a plasma generating chamber S1 and a processing chamber S2 provided below the plasma generating chamber S1, in the axis Z direction, by a partition plate 40 (to be described later).

The processing chamber 12 includes, for example, a first sidewall 12a, a second sidewall 12b, a bottom 12c, and a cover 12d. The first sidewall 12a has a substantially cylindrical shape extending in the axis Z direction, and defines the plasma generating chamber S1.

Gas lines P11 and P12 are formed in the first sidewall 12a. The gas line P11 extends from the outer surface of the first sidewall 12a and is connected to the gas line P12. The gas line P12 extends substantially annularly around the axis Z in the first sidewall 12a. The gas line P12 is connected to a plurality of injection ports H1 to inject a gas into the plasma generating chamber S1.

Further, the gas line P11 is connected with a gas source G1 via a valve V11, a mass flow controller M1, and a valve V12. The gas source G1 supplies a gas for plasma excitation. In the present exemplary embodiment, the gas supplied from the gas source G1 is, for example, Ar gas, O₂ gas, or H₂ gas. The gas source G1, the valve V11, the mass flow controller M1, the valve V12, the gas line P11, the gas line P12, and the injection ports H1 constitute a plasma excitation gas supply system. The plasma excitation gas supply system controls the flow rate of the gas supplied from the gas source G1 by the mass flow controller M1, and supplies the flow rate-controlled gas into the plasma generating chamber S1.

Further, the cover 12d is provided on the upper end of the first sidewall 12a. The cover 12d is formed with an opening, and an antenna 14 is provided in the opening. Further, a dielectric window 16 is formed just below the antenna 14 to seal the plasma generating chamber S1.

As the antenna 14 radiates microwaves into the plasma generating chamber S1, plasma of the gas supplied from the plasma excitation gas supply system is generated in the plasma generating chamber S1. In the present exemplary embodiment, the antenna 14 is, for example, a radial line slot antenna. The antenna 14 includes a dielectric plate 18, and a slot plate 20. The dielectric plate 18 shortens the wavelength of the microwaves, and has substantially a disc shape. The dielectric plate 18 is made of a dielectric such as, for example, quartz or alumina. The dielectric plate 18 is interposed between the top surface of the slot plate 20 and the metal bottom surface of a cooling jacket 22.

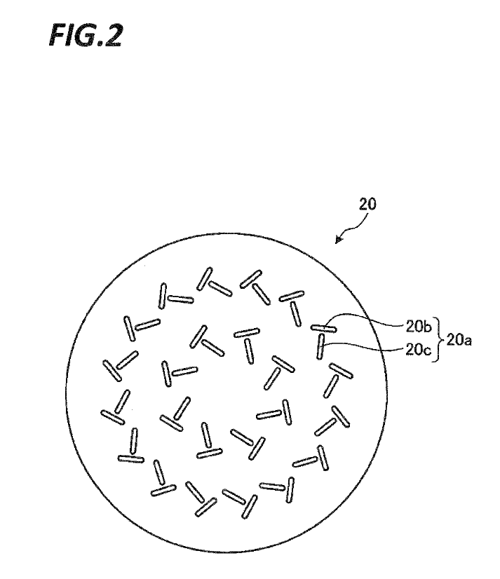

The slot plate 20 is a substantially disc-shaped metal plate including a plurality of slot pairs formed therein. FIG. 2 is a plan view illustrating an example of the slot plate 20. The slot plate 20 includes a plurality of slot pairs 20a formed therein. The plurality of slot pairs 20a are arranged in concentric circles which are radially spaced away from each other, in a circumferential direction in the plane of the slot plate 20. Each slot pair 20a includes two slot holes 20b and 20c, which are elongated holes extending in a direction intersecting with or orthogonal to each other.

The plasma processing apparatus 10 further includes a coaxial waveguide 24, a microwave generator 26, a tuner 28, a waveguide 30, and a mode converter 32. The microwave generator 26 generates microwaves having a frequency of, for example, 2.45 GHz. The microwave generator 26 is connected to the upper portion of the coaxial waveguide 24 via the tuner 28, the waveguide 30, and the mode converter 32. The coaxial waveguide 24 extends along an axis Z which is a central axis thereof. The coaxial waveguide 24 includes an outer conductor 24a and an inner conductor 24b. The outer conductor 24a has a cylindrical shape that extends around the axis Z. The lower end of the outer conductor 24a is electrically connected to the upper portion of the cooling jacket 22 having a conductive surface. The inner conductor 24b has a substantially cylindrical shape that extends along the axis Z, and is provided inside the outer conductor 24a. The lower end of the inner conductor 24b is connected to the slot plate 20 of the antenna 14.

The microwaves generated from the microwave generator 26 are propagated to the dielectric plate 18 through the coaxial waveguide 24. The microwaves propagated to the dielectric plate 18 are propagated to the dielectric window 16 primarily through slot holes 20b, 20c of the slot plate 20.

The dielectric window 16 has substantially a disc shape, and is made of, for example, quartz or alumina. The dielectric window 16 is formed just below the slot plate 20. The dielectric window 16 radiates the microwaves, which has been propagated from the antenna 14, to the plasma generating chamber S1. Accordingly, an electric field is generated just below the dielectric window 16 by the microwaves, and plasma is generated in the plasma generating chamber S1.

Below the first sidewall 12a, the second sidewall 12b extends continuously with the first sidewall 12a. The second sidewall 12b has a substantially cylindrical shape extending in the axis Z direction, and defines the processing chamber S2. A placing table 36 is provided in the processing chamber S2 to place a processing target substrate W thereon. In the present exemplary embodiment, the placing table 36 is supported by a support 38 that extends from the bottom 12c of the processing container 12 in the axis Z direction. In the present exemplary embodiment, the placing table 36 includes a temperature control mechanism such as a heater or a cooler, or an attracting and holding mechanism such as an electrostatic chuck.

Further, in the processing chamber S2, a gas line P21 extends annularly around the axis Z above the placing table 36. The gas line P21 is formed with a plurality of injection ports H2 to inject a gas into the processing chamber S2. The gas line P21 is connected with a gas line P22 that extends to the outside of the processing container 12 through the second sidewall 12b. The gas line P22 is connected with a gas source G2 via a valve V21, a mass flow controller M2, and a valve V22. The gas source G2 is a gas source of the processing gas used for the processing of the substrate W such as, for example, film formation or etching. As a processing gas for a film formation processing, a precursor gas such as, for example, dimethoxytetramethyldisiloxane (DMOTMDS) is used. The gas source G2, the valve V21, the mass flow controller M2, the valve V22, the gas line P21, the gas line P22, and the injection ports H2 constitute a processing gas supply system. The processing gas supply system controls the flow rate of the gas supplied from the gas source G2 by the mass flow controller M2, and supplies the flow rate-controlled gas into the processing chamber S2.

In the plasma processing apparatus 10 of the present exemplary embodiment, a partition plate 40 is provided between the plasma generating chamber S1 and the processing chamber S2. The plasma generating chamber S1 and the processing chamber S2 are separated from each other by the partition plate 40. The partition plate 40 is a substantially disc-shaped member, and supported by the first sidewall 12a. The partition plate 40 has a plurality of openings 40h that communicate the plasma generating chamber S1 and the processing chamber S2.

The partition plate 40 has a shielding property against ultraviolet rays generated in the plasma generating chamber S1. That is, the partition plate 40 may be made of a material that does not transmit ultraviolet rays. Further, in the present exemplary embodiment, when charged particles in the plasma generated in the plasma generating chamber S1 pass through the openings 40h while colliding with the inner walls defining the openings 40h, the partition plate 40 performs a charge exchange with the charged particles. Therefore, the partition plate 40 neutralizes the charged particles that pass through the openings, and releases the neutralized particles, that is, the neutral particles to the processing chamber S2. In the present exemplary embodiment, the charged particles are, for example, positively charged ions. Further, in the present exemplary embodiment, the partition plate 40 is made of an insulating material such as, for example, quartz or alumina.

In the present exemplary embodiment, the surface of the processing chamber S2 side of the partition plate 40 is coated with a conductive member 40a made of a conductive material such as, for example, a metal. The conductive member 40a is connected with a voltage applying unit 13a. The voltage applying unit 13a applies a DC voltage of a polarity that is opposite to the charge of the charged particles guided from the plasma generating chamber S1 into the processing chamber S2 through the openings 40h of the partition plate 40, to the conductive member 40a. In the present exemplary embodiment, the charged particles guided from the plasma generating chamber S1 into the processing chamber S2 through the openings 40h of the partition plate 40, are positively charged ions. Thus, the voltage applying unit 13a applies a negative DC voltage to the conductive member 40a. Further, the voltage applying unit 13a may apply an AC voltage to the conductive member 40a, or may apply square waves that alternately output a negative DC voltage of a predetermined magnitude and a negative DC voltage of a predetermined magnitude stepwise, to the conductive member 40a.

In the present exemplary embodiment, the ions in the plasma generated in the plasma generating chamber S1 are accelerated by the negative DC voltage applied to the conductive member 40a when passing though the openings 40h of the partition plate 40. Then, the neutral particles electrically neutralized by the contact with the inner wall of the openings 40h, are injected into the processing chamber S2 at a high speed.

The bottom 12c of the processing container 12 is connected to an exhaust pipe 48. The exhaust pipe 48 is connected with a pressure adjustor 50 and a vacuum pump 52. The pressure adjustor 50 and the vacuum pump 52 constitute an exhaust device. The plasma processing apparatus 10 may set the pressure of the plasma generating chamber S1 and the processing chamber S2 to an arbitrary pressure by adjusting the flow rate of the gas for plasma excitation by the mass flow controller M1, adjusting the flow rate of the processing gas by the mass flow controller M2, and adjusting the exhaust amount from the processing chamber S2 by the pressure adjustor 50.

The plasma processing apparatus 10 further includes a controller Cnt. The controller Cnt is, for example, a computer including a storage device in which a program is stored. The controller Cnt reads a program based on a recipe stored in the storage device, and controls respective parts of the plasma processing apparatus 10 in accordance with the read program. For example, the controller Cnt may control the supply of the gas for plasma excitation from the gas source G1 and the stop of the supply by transmitting a control signal to the valves V11 and V12, and control the flow rate of the gas for plasma excitation by transmitting a control signal to the mass flow controller M1. Further, the controller Cnt may control the supply of the processing gas from the gas source G2 and the stop of the supply by transmitting a control signal to the valves V21 and V22, and control the flow rate of the processing gas by transmitting a control signal to the mass flow controller M2. Further, the controller Cnt may control the exhaust amount by transmitting a control signal to the pressure adjustor 50. Further, the controller Cnt may control the power of the microwaves by transmitting a control signal to the microwave generator 26. Further, the controller Cnt may control the supply of the voltage to be applied to the conductive member 40a of the partition plate 40 and the stop of the supply, furthermore, the magnitude of the voltage to be applied to the conductive member 40a by transmitting a control signal to the voltage applying unit 13a. Furthermore, the controller Cnt may control the temperature of the placing table 36 by transmitting a control signal to the temperature control mechanism of the placing table 36.

For example, the controller Cnt supplies the gas for plasma excitation from the respective injection ports H1 into the plasma generating chamber S1, and supplies the processing gas from the respective injection ports H2 into the processing chamber S1, in a state where the substrate W is placed on the placing table 36. Then, the controller Cnt radiates microwaves from the antenna 14 to generate plasma in the plasma generating chamber S1. Then, the controller Cnt applies a predetermined voltage to the conductive member 40a of the partition plate 40 to guide the ions included in the plasma generated in the plasma generating chamber S1 to the openings 40h of the partition plate 40. Then, the particles neutralized by the contact with the inner wall of the openings 40h of the partition plate 40 when passing through the openings 40h, enter into the processing chamber S2 at a high speed, thereby exciting the processing gas supplied into the processing chamber S2. The substrate W placed on the placing table 36 in the processing chamber S2 is subjected to a predetermined processing such as, for example, film formation or etching by the processing gas excited by the neutral particles.

[Details of Partition Plate 40]

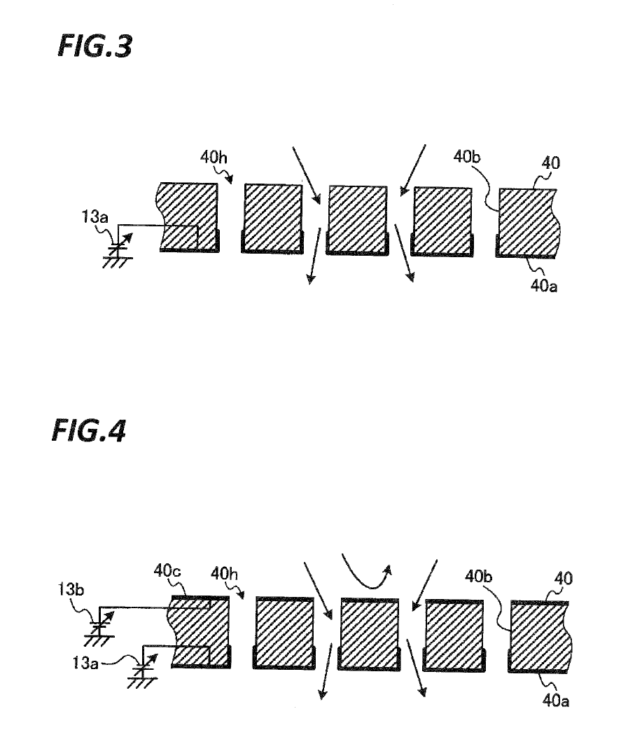

FIG. 3 is an enlarged cross-sectional view illustrating an exemplary configuration of the partition plate 40. In the present exemplary embodiment, the surface of the processing chamber S2 side of the partition plate 40 is coated with a conductive member 40a made of a conductive material such as, for example, a metal, for example, as illustrated in FIG. 3. The conductive member 40a is applied with a DC voltage supplied from the voltage applying unit 13a. Further, in the present exemplary embodiment, at least a part of the inner wall 40b of each opening 40h formed in the partition plate 40, is coated with the conductive member 40a, for example, as illustrated in FIG. 3. Therefore, the ions in the plasma generated in the plasma generating chamber S1 are more effectively guided to the openings 40h by the negative DC voltage applied from the voltage applying unit 13a to the conductive member 40a.

As such, the conductive member 40a provided on the surface of the processing chamber S2 side of the partition plate 40 is applied with a DC voltage that is opposite to the polarity of the charged particles guided from the plasma generating chamber S1 into the processing chamber S2. Therefore, the charged particles in the plasma generated in the plasma generating chamber S1 is more efficiently guided into the openings 40h. Thus, more neutral particles may be supplied to the processing chamber S2, and the amount of the charged particles colliding with the surface of the plasma generating chamber S1 side of the partition plate 40 may be reduced. Accordingly, consumption of the partition plate 40 due to the collision of the charged particles may be suppressed. Further, generation of particles of the partition plate 40 due to the collision of the charged particles may be suppressed.

Further, the conductive member 40a in the present exemplary embodiment is formed by coating a conductive material on the surface of the processing chamber S2 side of the partition plate 40, but the present disclosure is not limited thereto. For example, in another exemplary embodiment, the conductive member 40a may be formed of a conductive material such as, for example, a metal, as a separate member from the partition plate 40, and may be attached to the surface of the processing chamber S2 side of the partition plate 40.

As such, an exemplary embodiment of the plasma processing apparatus 10 has been described. As described above, the plasma processing apparatus 10 of the present exemplary embodiment may suppress consumption of the partition plate 40 and contamination of the processing target substrate W.

[Modification]

Next, a modification of the partition plate 40 will be described. FIG. 4 is an enlarged cross-sectional view illustrating an example of the partition plate 40 in Modification 1. In the partition plate 40 in the present modification, the surface of the plasma generating chamber S1 side of the partition plate 40 is further coated by a conductive member 40c made of a conductive material such as, for example, a metal. The conductive member 40c is connected with a voltage applying unit 13b. The voltage applying unit 13b applies a DC voltage of a polarity that is equal to the polarity of the charged particles (e.g., ions) guided from the plasma generating chamber S1 to the processing chamber S2 (e.g., a positive DC voltage), to the conductive member 40c.

As such, in the partition plate 40 of the present modification, the conductive member 40c coated on the plasma generating chamber S1 side is applied with a DC voltage of a polarity that is equal to the polarity of the charged particles guided from the plasma generating chamber S1 to the processing chamber S2. Thus, the amount of the charged particles colliding with the surface of the plasma generating chamber S1 of the partition plate 40 may be further reduced. Accordingly, consumption of the partition plate 40 due to the collision of the charged particles or generation of particles may be further suppressed.

Further, the magnitude of the DC voltage applied to the conductive member 40c by the voltage applying unit 13b may be substantially equal to the magnitude of the plasma potential of the plasma generated in the plasma generating chamber S1. Further, in another example, the conductive member 40c may be connected to a reference potential (ground) of the plasma processing apparatus 10 instead of the voltage applying unit 13b. Even in this case, since the surface of the plasma generating chamber S1 of the partition plate 40 is suppressed from being charged with a charge of a polarity that is opposite to the charge of the charged particles guided from the plasma generating chamber S1 to the processing chamber S2, the amount of the charged particles colliding with the surface of the plasma generating chamber S1 of the partition plate 40 may be further reduced.

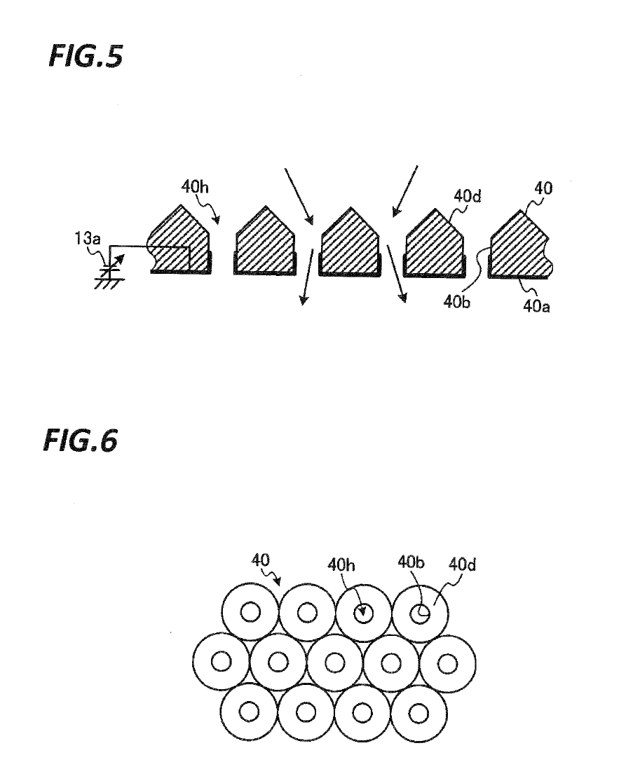

FIG. 5 is an enlarged cross-sectional view illustrating an example of the partition plate 40 in Modification 2. In the partition plate 40 of the present modification, a tapered surface 40d is formed on the plasma generating chamber S1 of each opening 40h. Thus, in each opening 40h, the opening area of the plasma generating chamber S1 side is wider than the opening area of the processing chamber S2 side. The illustration of the surface of the plasma generating chamber S1 side of the partition plate 40 may be found, for example, in FIG. 6. FIG. 6 is a plan view illustrating an example of the partition plate 40 in Modification 2.

Here, as the opening area of each opening 40h is wider, the ions in the plasma of the plasma generating chamber S1 may be efficiently guided into the opening 40h. However, as the opening area of each opening 40h is wider, the mechanical strength of the partition plate 40 is reduced. Thus, as for each opening 40h, in the case where the opening area of the plasma generating chamber S1 side is equal to the opening area of the processing chamber S2 side, the opening area of the plasma generating chamber S1 side cannot be set to be so wide in order to maintain the mechanical strength of the partition plate 40 to some extent.

In contrast, in the partition plate 40 of Modification 2 illustrated in FIGS. 5 and 6, a tapered surface 40d is formed on the plasma generating chamber S1 of each opening 40h. Accordingly, the opening area of the plasma generating chamber S1 side may be set to be wide while maintaining the mechanical strength of the partition plate 40 to some extent. Therefore, the charged particles in the plasma generated in the plasma generating chamber S1 is more efficiently guided into the openings 40h.

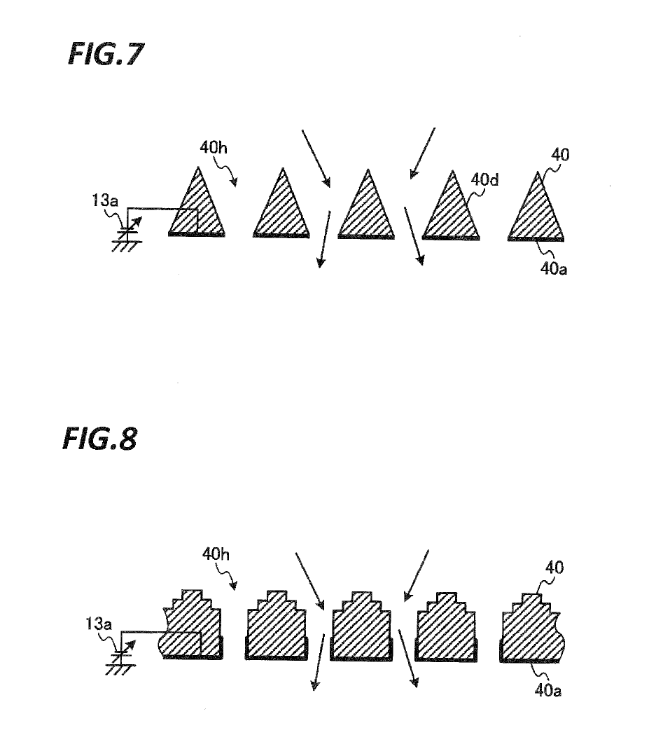

FIG. 7 is an enlarged cross-sectional view illustrating an example of the partition plate 40 in Modification 3. In the partition plate 40 of the present modification, a tapered surface 40d is formed on the whole inner wall of each opening 40h. Thus, in each opening 40h, the opening area of the plasma generating chamber S1 side is set to be wider than the opening area of the processing chamber S2 side. Accordingly, in the partition plate 40 of Modification 3, the opening area of the plasma generating chamber S1 side may be set to be wide while maintaining the mechanical strength of the partition plate 40 to some extent. Therefore, the charged particles in the plasma generated in the plasma generating chamber S1 is more efficiently guided into the openings 40h.

Thus, in each opening 40h, when the opening area of the plasma generating chamber S1 side is formed to be wider than the opening area of the processing chamber S2 side, an inclined surface is not necessarily formed on the inner wall. For example, as in Modification 4 illustrated in FIG. 8, each opening 40h may be formed such that the opening area is narrower stepwise as it proceeds from the plasma generating chamber S1 side to the processing chamber S2 side.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container; and
a partition plate made of an insulating material, having a plurality of openings, and configured to partition an inside of the processing container into a plasma generating chamber and a processing chamber,
wherein a first conductive member made of a conductive material is provided on a surface of the processing chamber side of the partition plate, and
the first conductive member is applied with at least one of an AC voltage and a DC voltage of a polarity that is opposite to a polarity of charged particles guided from the plasma generating chamber into the processing chamber through each of the openings.

2. The plasma processing apparatus of claim 1, wherein the first conductive member is formed by coating the conductive material on the surface of the processing chamber side of the partition plate.

3. The plasma processing apparatus of claim 2, wherein at least a part of an inner wall of each of the plurality of openings is coated with the conductive material, and
the first conductive member is conductive with the conductive material coated on the inner wall of each of the plurality of openings.

4. The plasma processing apparatus of claim 1, wherein the first conductive member is formed as a member separate from the partition plate, and attached to the surface of the processing chamber side of the partition plate.

5. The plasma processing apparatus of claim 1, wherein a second conductive member made of a conductive material is provided on the plasma generating chamber side of the partition plate, and
the second conductive member is connected to a reference potential of the processing container.

6. The plasma processing apparatus of claim 1, wherein a second conductive member made of a conductive material is provided on the plasma generating chamber side of the partition plate, and
the second conductive member is applied with a DC voltage of a polarity that is equal to a polarity of charged particles included in plasma generated in the plasma generating chamber, and guided into the processing chamber through each of the openings.

7. The plasma processing apparatus of claim 6, wherein a magnitude of the DC voltage applied to the second conductive member is substantially equal to a magnitude of a plasma potential of the plasma generated in the plasma generating chamber.

8. The plasma processing apparatus of claim 6, wherein each of the plurality of openings has an opening area at the plasma generating chamber side wider than an opening area at the plasma generating chamber side.
